(19) United States
(12) Patent Application Publication
(10) Pub. No.: US 2011/0133192 A1
(43) Pub. Date: Jun. 9, 2011

(54) METHOD OF FORMING CONDUCTIVE PATTERN AND ORGANIC THIN FILM TRANSISTOR

(75) Inventor: Takeshi Hakii, Sagamihara-shi (JP)

(73) Assignee: Konica Minolta Holdings, Inc., Tokyo (JP)

(21) Appl. No.: 13/054,913

(22) PCT Filed: Jun. 29, 2009
(86) PCT No.: PCT/JP2009/061840

§ 371 Date: Jan. 19, 2011

(30) Foreign Application Priority Data
Jul. 24, 2008 (JP) 2008-190798

(51) Int. Cl. H01L 51/10; G03F 7/20

(52) U.S. Cl. 257/57; 430/315; 257/E51.005

(57) ABSTRACT

In the present invention, provided is a method of forming a conductive pattern exhibiting excellent adhesion of the conductive pattern to a substrate and high fine line reproduction via a simple process, and an organic thin film transistor exhibiting excellent element properties. Disclosed is a method of forming a conductive pattern, possessing a step of treating a substrate surface employing a compound represented by the following Formula (1), a step of decomposing the compound represented by Formula (1) via a photocatalytic action, and a plating step: Formula (1) (R)ₙ—Si(A)₃₋ₙ-(B) wherein R represents an alkyl group having 8 carbon atoms or less, A represents an alkoxy group or a halogen atom, B represents a substituent comprising a SH group, and n represents an integer of 0-2.

### TECHNICAL FIELD

The present invention relates to a new method of forming a conductive pattern, and an organic thin film transistor thereof.

### BACKGROUND

In order to prepare an electronic circuit having a fine conductive pattern or the like, in the past, conventionally taken has been a photolithography method by which a resist layer is laminated on a base material in which a conductive layer is formed, the resulting is exposed to light via a photomask having a desired pattern, and the undesired resist layer is removed after a developing treatment. However, there was a problem such that this photolithography method was cumbersome because of a number of steps comprised in the method, in addition to a cost problem, and further, there was a problem such that it produced an environmental load to discard a removed resist layer.

In order to solve such a problem, in Patent Document 1, studied has been a method by which after a monomolecular film made of a long-chain alkyl based silane coupling agent is formed in a base material, it is exposed to light in the form of a pattern employing a Xe exicimer lamp to decompose a part of the foregoing monomolecular film, and a conductive pattern is formed by utilizing a difference between adhesion of a region where the monomolecular film remains, to metal and adhesion of a region where the monomolecular film is decomposed, to metal.

After considerable effort during intensive studies of the above-described technique, the inventor has found out that a method disclosed in Patent Document 1 is advantageous in view of no application of a vacuum process, but the method produces many restrictions to apparatuses since a lamp exhibiting a wavelength of less than 300 nm is to be employed to decompose the monomolecular film, and further tends to produce adverse effect on material, resulting in appearance of drawbacks such as lowering of adhesion and undesired property variation.

Further in Patent Documents 2 and 3, studied is a method by which an organic molecules are decomposed by utilizing a titanium dioxide photocatalytic action. The method disclosed in Patent Documents 2 and 3 produces a drawback such that conductive pattern adhesion drops with increase of resolution since a silane coupling agent is excessively decomposed during pattern formation.

In recent years, an organic thin film transistor (organic TFT, i.e., Organic Thin Film Transistor OTFT) has drawn attention as a next general flat panel display device with high quality and low price or a switching element for driving pixels of electronic paper.

An organic thin film transistor can be provided as an application example for a method of forming a conductive pattern in the present invention. An organic thin film transistor has substantially the same structure as that of a silicon thin film transistor, but differs from a silicon thin film transistor in that it employs an organic material in place of silicon in the semiconductor active layer region. The organic thin film transistor can be manufactured using a no vacuum evaporator but an ink jet method or a printing method, and therefore, the organic thin film transistor can be manufactured easily and at low cost as compared with a silicon TFT. The organic thin film transistor has advantages that it is suitably applied to an electronic circuit board capable of being bent and folded, which is not broken by impact. Since an organic thin film transistor having such advantages is useful for a product to be bent at a time when an element is prepared on the wide area, and a low process temperature is required, and it is expected as an element for driving a matrix of a large size display or an element for driving an organic EL or electronic paper. Development of the organic thin film transistor done by many companies is in progress.

Operation principle of an organic thin film transistor is to control resistance by voltage. The gate voltage being controlled, the insulating layer works to generate an accumulation layer in a carrier at the contact interface between the organic semiconductor layer and the insulating layer, whereby conducting current between the two ohm contacts is controlled.

Conventionally, a source electrode, a drain electrode, a gate electrode, a contact electrode and a pixel electrode in an organic thin film transistor have been formed via a vacuum process such as a sputtering method, resulting in cost increase because of the vacuum process.

An ink jet method (refer to Patent Document 4) or a screen printing method (refer to Patent Document 5) has been studied as an electrode formation method using no vacuum process.

However, techniques disclosed in the above-described Patent Documents 4 and 5 have been studied in detail. As a result, it has been found that in the method disclosed in the Patent Document 4, in which a source electrode and a drain electrode are formed via an ink jet method, controlling affinity of ink to a substrate, additives contained in the ink remain in the electrodes, which adversely affects transistor performance.

It has been also found that the method disclosed in the Patent Document 5, which forms a source electrode and a drain electrode via a screen printing method employing a silver paste, provides neither each of source and drain electrodes with high resolution, nor a transistor with high speed and power consumption.

### PRIOR ART DOCUMENT

### Patent Document

Patent Document 1: Japanese Patent Open to Public Inspection (O.P.I.) Publication No. 2005-216907
Patent Document 2: Japanese Patent O.P.I. Publication No. 2004-13042
Patent Document 3: Japanese Patent O.P.I. Publication No. 2001-11644
Patent Document 4: Japanese Patent O.P.I. Publication No. 2003-318190
Patent Document 5: Japanese Patent O.P.I. Publication No. 2005-72188

### DISCLOSURE OF THE INVENTION

### Problems to be Solved by the Invention

The present invention has been made on the basis of the above-described problem, and it is an object of the present invention to provide a method of forming a conductive pattern exhibiting excellent adhesion of the conductive pattern to a substrate and high fine line reproduction via a simple process, and an organic thin film transistor exhibiting excellent element properties.

### Means to Solve the Problems

The above-described object is accomplished by the following structures.

(Structure 1) A method of forming a conductive pattern, comprising the steps of treating a substrate surface employing a compound represented by the following Formula (1); decomposing the compound represented by Formula (1) via a photocatalytic action; and conducting a plating treatment,

(R)ₙ—Si(A)₃₋ₙ-(B) Formula (1)

wherein R represents an alkyl group having 8 carbon atoms or less, A represents an alkoxy group or a halogen atom, B represents a substituent comprising a SH group, and n represents an integer of 0-2.

(Structure 2) The method of Structure 1, wherein the compound represented by Formula (1) comprises a triazine ring.

(Structure 3) The method of Structure 1 or 2, wherein the photocatalytic action comprises a titanium dioxide photocatalytic action.

(Structure 4) The method of Structure 3, wherein the step of decomposing the compound represented by Formula (1) comprises a light exposure step employing a photomask in which a titanium dioxide film is comprised.

(Structure 5) The method of Structure 4, wherein a light source used in the light exposure step has a main wavelength of 300-400 nm.

(Structure 6) The method of Structure 5, wherein the light source comprises a high-pressure mercury lamp.

(Structure 7) The method of any one of Structures 1-6, wherein the plating step comprises a catalyst-carrying process and an electroless plating process.

(Structure 8) An organic thin film transistor comprising a conductive pattern formed by the method of any one of Structures 1-7.

(Structure 9) The organic thin film transistor of Structure 8, wherein the conductive pattern comprises a source electrode or a drain electrode.

### Effect of the Invention

In the present invention, provided can be a method of forming a conductive pattern exhibiting excellent adhesion of the conductive pattern to a substrate and high fine line reproduction via a simple process, and an organic thin film transistor exhibiting excellent element properties.

### BRIEF DESCRIPTION OF THE DRAWINGS

FIG. 1 is a step diagram showing a method of forming a conductive pattern in the present invention.

FIG. 2 is a schematic cross-sectional view showing an example of a configuration of an organic thin film transistor in the present invention.

### DESCRIPTION OF THE PREFERRED EMBODIMENTS

After considerable effort during intensive studies on the basis of the above-described situation, the inventors have found out that a method of forming a conductive pattern exhibiting excellent adhesion of the conductive pattern to a substrate and high fine line reproduction via a simple process can be obtained by a method of forming a conductive pattern possessing a step of treating a substrate surface employing a compound represented by foregoing Formula (1); a step of decomposing the compound represented by foregoing Formula (1) via a photocatalytic action; and a plating step.

Further, it was found out that an organic thin film transistor prepared by the method of forming a conductive pattern exhibited excellent element properties.

The reasons for obtaining excellent adhesion of a conductive pattern to a substrate, and high fine line reproduction via a method of forming a conductive pattern in the present invention are provided below.

1. Utilizing of a compound exhibiting photocatalytic action makes light exposure wavelength to be a longer wavelength.
2. Adjacent SH groups are present near.
3. Silane coupling agent density per unit area is high.

Next, the present invention will be described in detail.

[Compound Represented by Formula (1)]

In foregoing Formula (I), R represents an alkyl group having 8 carbon atoms or less, and preferably represents a lower alkyl group having 1-4 carbon atoms.

A represents an alkoxy group or a halogen atom, and examples of the alkoxy group include lower alkoxy groups each having 1-4 carbon atoms, such as a methoxy group, an ethoxy group, a propoxy group, a butoxy group and so forth. Specifically preferable are a methoxy group, and an ethoxy group. The alkoxy group may have a substituent. Among halogen atoms, a chlorine atom is preferable.

B represents a substituent containing an SH group, and may be an aliphatic or (hetero) aromatic group containing at least one mercapto group and preferably at least two mercapto groups in the structure.

Symbol n is an integer of 0-2.

When a compound represented by Formula (1) comprises a triazine ring, adhesiveness is preferably improved, since adjacent SH groups are present near; there appears high sensitivity because of occurrence of effective electron transfer; and further, silane coupling agent density per unit area is high.

Examples of compounds represented by Formula (1) are shown below.

A-1: triethoxysilyl-propylamino-triazine-dithiol
A-2: γ-mercaptopropyl-trimethoxy silane
A-3: 3-mercaptopropylmethyldimethoxy silane
A-4: mercaptopropyltriethoxy silane
A-5: γ-mercaptopropylmethyldimethoxy silane
A-6: γ-mercaptopropyltrichloro silane

Among compounds represented by Formula (1) described above, a compound having a triazine ring is specifically preferable. For example, A-1 can be easily prepared via condensation reaction of γ-propyltriethoxy silane with a corresponding mercaptoamine, in this case, 1-amino-3,5-dimercaptotriazine (as disclosed in Japanese Patent O.P.I. Publication No. 2001-316872).

<<Method of Forming Conductive Pattern>>

It is a feature that a method of forming a conductive pattern in the present invention possesses a treating step with a compound represented by foregoing Formula (1); a step of decomposing the compound represented by foregoing Formula (1) via a photocatalytic action; and a plating step.

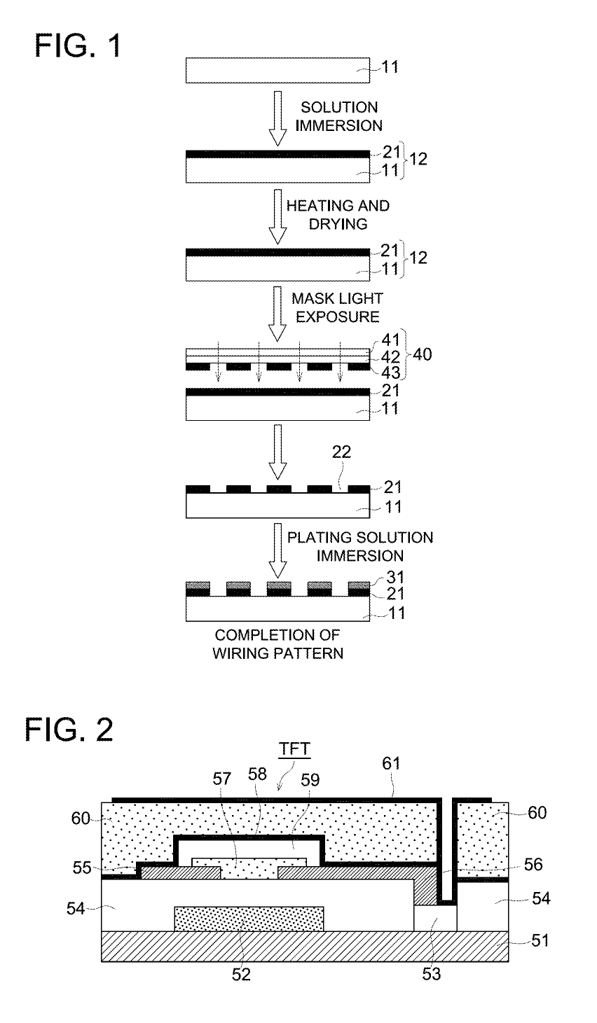

FIG. 1 is a step diagram showing a method of forming a conductive pattern in the present invention.

Substrate 11 is subjected to a corona discharge treatment, and subsequently immersed in a solution of a compound represented by Formula (1), followed by heating and drying to obtain base material 12 possessing layer 21 containing a compound represented by Formula (1).

Separately, a compound exhibiting photocatalytic action, for example, a disperse material containing titanium dioxide is coated on the surface of fused quartz 41, followed by calcination to form titanium dioxide layer 42, and a Cr layer is subsequently formed on titanium dioxide layer 42 to obtain photomask 40 after forming a pattern formed from Cr layer 43 by etching only the Cr layer via a photolithography method.

Next, a distance between a surface of base material 12, having been treated employing a compound represented by Formula (1), and titanium layer 42 in photomask 40 is set to, for example, 50 nm for light exposure employing, for example, a high-voltage mercury lamp. As to this light exposure, the region having been exposed to light forms region 22 in which a compound represented by Formula (1) is decomposed by active oxygen generated via a photocatalytic action, but the region having been unexposed to light forms region 21 where the compound represented by Formula (1) remains.

Finally, after immersing the resulting, for example, in a Pd catalyst solution, it is subjected to a drying treatment, and an immersing treatment in an electroless copper plating solution, further followed by drying to form a conductive pattern formed from copper 31.

[Step of Treating with Compound Represented by Formula (1)]

It is a feature that a solution containing a compound represented by foregoing Formula (1) is brought into contact with a member to be formed to connect the compound represented by foregoing Formula (1) to the foregoing member to be formed via siloxane bonding. A solvent used in a solution containing a compound represented by Formula (1) may be any solvent such as water, a water based solvent, an organic solvent or the like, as long as it dissolves the compound represented by Formula (1), but an alcoholic solvent is preferred in view of handling and drying properties, and ethanol or isopropanol is more preferred. A solvent used for a solution containing a compound represented by Formula (1) may be any solvent such as water, a water based solvent, an organic solvent or the like, as long as it is a solvent dissolved by the compound represented by Formula (1). However, as the solvent, an alcoholic solvent is preferable in view of handling and a drying property, and ethanol and isopropanol are more preferable.

Further, as a pretreatment of an electrode to be brought into contact with a solution containing a compound represented by Formula (1), usable are commonly known treatment processes such as cleaning with alcohol, cleaning with an acid or alkaline solution, cleaning with a surfactant solution, an atmospheric pressure plasma treatment, a UV ozone treatment and so forth. Of these, a UV ozone treatment is preferably conducted after cleaning with an alkaline solution.

[Step of Decomposing Compound Represented by Formula (1)]

Upon light exposure with a light source having a main wavelength of 300-400 nm via a photomask possessing a layer containing a compound exhibiting photocatalytic action, in the region having been exposed to light, a compound represented by Formula (1) is decomposed with an active oxygen generated by the photocatalytic action, and in the region unexposed to light, the compound represented by Formula (1) remains therein.

Examples of the compound exhibiting photocatalytic action in the present invention include titanium dioxide, lead sulfide, zinc sulfide, tungsten oxide, iron oxide, zirconium oxide, cadmium selenide, strontium titanate and so forth. These may be used singly or in combination with at least two kinds. Further, these are possible to be used in combination with a commonly known photocatalyst other than those described above. Among the above-described photocatalysts, preferable is titanium dioxide not only having a specifically high photocatalytic function, but also exhibiting chemical stability and high safety together with low cost.

Titanium dioxide may be amorphous, but may also have a specific crystalline structure. Examples of the specific crystalline structure include a rutile type structure, an anatase type structure and a brookite type structure, but specifically, the anatase type structure is preferably used Since the smaller the titanium dioxide, the higher the photocatalytic activation is, titanium dioxide particles prepared via a sol-gel method are preferably used. However, since secondary particles (an aggregate of primary particles) tends to become large in size while primary particles made of titanium dioxide become small in size, a titanium dioxide sol may be used Titanium dioxide particles preferably have an average particle diameter of 5-20 nm. Particles having an average particle diameter of less than 5 nm are different to be prepared, and particles having an average particle diameter exceeding 50 nm exhibit degraded photocatalytic activation. Particles having an average particle diameter of 5-20 nm are more preferable.

It is a feature that a photomask of the present invention has a layer made of a compound exhibiting photocatalytic action. For example, a titanium dioxide-dispersed material having a primary particle diameter of 5-20 nm is coated on the fused quartz by a spin coating method, followed by drying to form a titanium dioxide layer exhibiting photocatalytic action, and a Cr layer having a desired pattern is further formed on the titanium dioxide layer via sputtering and photolithography to obtain a photomask. As to a photomask of the present invention, preparation of a fused quartz, a titanium dioxide layer and a Cr layer in order is not specifically specified, as long as there is no fused quartz between the surface having treated employing a compound represented by Formula (1) and the titanium dioxide layer during light exposure,

The titanium dioxide layer preferably has a thickness of 10-1000 nm in view of an effect produced via photocatalytic action.

A distance between a photomask and a base material in which the substance surface has been treated employing a compound represented by Formula (1) is preferably 50-1000 nm in view of an active oxygen effectively produced via photocatalytic action and formation accuracy of a wiring pattern. Only a compound represented by Formula (1) in the region having been exposed to light is selectively decomposed via exposure to light in the form of a pattern in a light exposure step of the present invention, and a conductive pattern exhibiting high accuracy and high adhesion can be prepared since a metal wiring pattern is formed by producing a difference between force bonded to a metal compound in the region having been exposed to light and another force bonded to a metal compound in the region having been unexposed to light. Exposure to light with a light source having a main wavelength of 300-600 nm is preferable since degradation of a conductive pattern caused by deterioration of a substrate and undesired property variation of another functional material are generated when using a light source having a main wavelength of 300-600 nm for exposure to light. A high-pressure mercury lamp is listed as a light source having a main wavelength of 300-600 nm.

[Plating Step]

Since a compound represented by Formula (1) exhibits high adhesion to metal, the region to which metal is easy to adhere and the region to which metal is different to adhere can be produced by the foregoing light exposure step. A plating layer can be formed selectively in the region unexposed to light by conducting a plating treatment after the forgoing light exposure step. A troublesome treatment such as photolithography or the like to form a conductive pattern is omitted, and the conductive pattern can be obtained simply in a short period of time. Further, since an anchor portion is bonded with an —O—Si group, a plating film exhibiting excellent adhesion strength can be obtained.

In the present invention, a commonly known plating methods are applicable, but among these, an electroless plating process is preferably applied since a conductive pattern having low resistance can be subjected to a plating treatment simply at low cost with no troublesome step.

The plating treatment conducted via an electroless plating process is a method by which a plating agent is brought into contact with a conductive pattern containing metal particles acted as plating catalysts. The metal particles as plating catalysts are brought into contact with the plating agent, and conductive pattern portions are subjected to electroless plating to further obtain excellent conductivity.

For a plating agent usable in a plating treatment of the present invention, for example, employed is a solution in which a metal ion to be deposited as a plating material is evenly dissolved, and a reductant together with a metal salt is contained. Herein, a solution is conventionally used, but the present invention is not limited thereto as long as electroless plating is applicable, and a gaseous or powder plating agent is also applicable.

Specifically, as the metal salt, applicable are a halide, nitrate, sulfate, phosphate, borate, acetate, tartrate, and citrate of at least one kind of metal selected from the group consisting of Au, Ag, Cu, Ni, Co, and Fe. As the reductant, applicable are hydrazine, a hydrazine salt, borohalide, hypophoshite, hyposulfite, alcohol, aldehyde, carboxylic acid, and carboxylate. Any element such as boron, phosphor, nitrogen or the like contained in the reductant may be contained in an electrode to be deposited. Alternatively, an alloy may be formed employing an admixture of these metal salts.

For the plating agent, an admixture of the metal salt and the reductant may be applicable, and the metal salt and the reductant may also be applied separately. Herein, in order to form an electrode pattern more clearly, an admixture of the metal salt and the reductant is preferably applied. Further, when the metal salt and the reductant are applied separately, the metal salt is initially placed on a conductive pattern portion, and then the reductant is placed to form a more stable electrode pattern.

The plating agent may contain additives such as a buffer for pH control and a surfactant, if desired. Further, as a solvent used in a solution, added may be an organic solvent such as alcohol, ketone or ester other than water.

A composition of the plating agent is a composition obtained by adding a metal salt of metal to be deposited, a reductant, and an additive and an organic solvent, if desired, but the concentration and the composition can be adjusted depending on the deposition rate. Further, the deposition rate may also be adjusted by controlling the temperature of a plating agent. Examples of this temperature-adjusting method include a method by which the temperature of the plating agent is adjusted and a method by which the temperature is controlled by heating or cooling a substrate prior to immersion in the case of being immersed, for example, in the plating agent. Further, the film thickness of a metal thin film to be deposited can also be adjusted with a duration of immersion in a plating agent.

[Substrate]

Usable examples substrates employed in the present invention include synthetic plastic films made of polyolefins such as polyethylene and polypropylene, polycarbonates, cellulose acetate, polyethylene terephthalate, polyethylenedinaphthalene dicarboxylate, polyethylene naphthalates, polyvinyl chloride, polyimide, polyvinyl acetals, or polystyrene. Further, syndiotactic-structured polystyrenes are preferably used. These can be obtained by methods disclosed in, for example, Japanese Patent O.P.I. Publication No. 62-117708, Japanese Patent O.P.I. Publication No. 1-46912, and Japanese Patent O.P.I. Publication No. 1-178505. Further listed are metal substrates made of stainless steel, supports made of paper such as baryta paper and resin-coated paper, a support in which a reflection layer is formed on the above-described plastic film, and those described, as a support, in Japanese Patent O.P.I. Publication No. 62-253195 (pages 29-31). Also preferably usable are those disclosed on page 28 of RD No. 17643, those disclosed from the right column on page 647 to the left column on page 648 of RD No. 18716, and those disclosed on page 879 of RD No. 307105. As disclosed in U.S. Pat. No. 4,141,735, these supports may be subjected to a thermal treatment at a temperature below Tg, so that those for which core-set curl is difficult to be generated are usable. Further, the surface of each of these supports may be subjected to a surface treatment for the purpose of improving adhesion of the support to another constituent layer. In the present invention, a glow discharge treatment, a UV radiation treatment, a corona treatment and a flame treatment are usable. Further usable are supports described on pages 44-149 of Kochi Gijutsu (commonly known technology) No. 5 (published by AZTEC Japan., Mar. 22, 1991). Further listed are those described on page 1009 of RD No. 308119 and in the item “Supports” on page 108 of Product Licensing Index Vol. 92. In addition, usable are glass substrates and epoxy resins in which glass is kneaded.

[Organic Thin Film Transistor]

A method of forming a conductive pattern in the present invention can be applied for preparation of an organic thin film transistor. Examples of the conductive pattern formed in the organic thin film transistor include a pixel electrode, a source electrode, a drain electrode, a gate electrode and a contact electrode. Electrodes formed via the method of forming a conductive pattern in the present invention are preferably a source electrode and a drain electrode.

[Structure of Organic Thin Film Transistor]

Next, each of the components constituting the organic thin film transistor of the invention will be described in detail.

FIG. 2 is a schematic cross-sectional diagram showing an example of a structure of the organic thin film transistor of the present invention.

In FIG. 2, the organic thin film transistor TFT is equipped with substrate 51, gate electrode 5, contact electrode 53, source electrode 55, drain electrode 56, and organic semiconductor layer 57. Gate electrode 52 is provided on substrate 51, and insulating layer 54 including a gate insulating layer is provided so as to cover gate electrode 52. A space forming a channel of organic semiconductor layer 57 is formed, and source electrode 55 and drain electrode 56 are provided on insulating layer 44. Organic semiconductor layer 57 is formed at the space between source electrode 55 and drain electrode 56 to connect these source and drain electrodes. Numerals 58, 59, 60 and 61 represent passivation layers, a photosensitive insulating layer and s pixel electrode, respectively.

Next, the structure, material and process of each member constituting an organic thin film transistor will be described.

Substrates are not specifically limited, and for example, glass or a resin sheet such as a flexible plastic film is usable for the substrates. Specific examples of the plastic film include polyethylene terephthalate (PET), polyethylene naphthalate (PEN), polyethersulfone (PES), polyetherimide, polyether ether ketone, polyphenylene sulfide, polyallylate, polyimide, polycarbonate (PC), cellulose triacetate (TAC), cellulose acetate propionate (CAP) and so forth. Use of such a plastic film makes it possible to decrease weight, enhance portability, and enhance durability against impact, in comparison to glass.

Next, a gate electrode and a contact electrode are not specifically limited as long as they are formed of a conductive material, wherein the material is preferably a metal material exhibiting sufficient conductivity. Examples thereof include Al, Cr, Ag, Mo and those subjected to doping.

In order to form the gate electrode and the contact electrode, a conductive layer is to be formed on a substrate. As a method of forming this conductive thin film, a method of forming a conductive thin film in the present invention is preferably usable.

A commonly known evaporation or sputtering is also usable by employing raw material as the above-described material. the material. Thereafter, a commonly known photolithography treatment (coating of resist, light exposure and development) and an etching treatment are conducted to form a gate electrode.

Further, as a method of forming a gate electrode and a contact electrode, there is an ink jet method or a printing method such as letter press printing, intaglio printing or screen printing carried out employing a fluid electrode material.

As a conductive particle dispersion, there is a conductive particle dispersion such as a paste or ink in which conductive particles comprised of metals etc. are dispersed in water, an organic solvent or their mixture preferably in the presence of a dispersion stabilizer of an organic material. In the dispersion as described above, a dispersion medium containing water mainly as is preferred, since the conductive layer is formed on an organic semiconductor.

Usable examples of metal materials for conductive particles (metal particles) include platinum, gold, silver, cobalt, nickel, chromium, copper, iron, tin, antimony lead, tantalum, indium, palladium, tellurium, rhenium, iridium, aluminum, ruthenium, germanium, molybdenum, tungsten, zinc and so forth. Platinum, gold, silver, copper, cobalt, chromium, indium, nickel, palladium, molybdenum, and tungsten, each having a work function of 4.5 eV or more, are specifically preferable.

Further, there can preferably be utilized commonly known conductive polymers exhibiting conductivity enhanced via doping such as conductive polyaniline, conductive polypyrrole, conductive polythiophene or a complex (PEDOT/PSS) of polyethylenedioxy thiophene and polystyrene sulfonic acid. Among the above, those are preferred which exhibit low resistance in the interface to be in contact with the semiconductor layer.

A source electrode, a drain electrode, and a pixel electrode can be formed in the same manner as described above in the gate electrode.

Materials constituting an organic semiconductor layer are not specifically limited and usable examples thereof include various condensed polycyclic aromatic compounds or conjugated compounds.

Examples of the condensed polycyclic aromatic compounds include compounds such as anthracene, tetracene, pentacene, hexacene, heptacene, phthalocyanine, porphyrin and so forth, and derivatives thereof.

Examples of the conjugated compounds include polythiophene and oligomers thereof, polypyrrole and oligomers thereof, polyaniline, polyphenylene and oligomers thereof, polyphenylene vinylene (PPV) and oligomers thereof, polyethylene vinylene and oligomers thereof, polyacetylene, polydiacetylene, tetrathiafluvalene compounds, quinone compounds, cyano compounds such as tetracyanoquinodimethane, and fullerene, and their derivatives or mixtures.

In an organic thin film transistor of the present invention, an organic semiconductor material constituting an organic semiconductor layer is preferably an oligomer having an average molecular weight of 5,000 or less, and as an oligomer preferably used in the present invention, listed is a thiophene oligomer.

The thiophene oligomer preferably used in the present invention is a thiophene oligomer which contains at least two continuous substituted thiophene ring repeating units and at least two continuous unsubstituted thiophene ring repeating units, and has 8-40 thiophene rings. The number of the foregoing thiophene rings is preferably 8-20.

The organic semiconductor layer may be subjected to a so-called doping treatment by incorporating each of materials having a functional group such as an acrylic acid, acetamide, a dimethylamono group, a cyano group, a carboxyl group, a nitro group and so forth; each of materials working as an acceptor which accepts electrons such as benzoquinone derivatives, tetracyanoethylene and tetracyanoquinodimethane, and their derivatives; each of materials having a functional group such as an amino group, a triphenyl group, an alkyl group, a hydroxyl group, an alkoxy group, a phenyl group and so forth: and each of materials working as a donor which donates electrons such as substituted amines such as phenylenediamine, anthracene, benzoanthracene, substituted benzoanthracenes, pyrene, substituted pyrene, carbazole and its derivatives, tetrathiafulvalene and its derivatives, and so forth.

The doping means that an electron accepting molecule (acceptor) or an electron donating molecule (donor) is incorporated in the organic semiconductor layer as a dopant. Accordingly, the layer, which has been subjected to doping, is one containing the above-described condensed polycyclic aromatic compounds and the dopant. As a dopant used in the present invention, a commonly known dopant is usable.

The organic semiconductor layer can be formed via a commonly known method. Examples thereof include a vacuum evaporation method, a CVD (Chemical Vapor Deposition) method, a laser evaporation method, an electron beam evaporation method, a spin coating method, a dip coating method, a bar coating method, a die coating method, and a spray coating method, as well as methods such as screen printing, ink-jet printing and blade coating.

Further, examples of patterning of the organic semiconductor layer include patterning conducted via a photolithography treatment after mask evaporation and formation of a film on the entire surface (when a vacuum evaporation method is used), and direct patterning such as ink jet printing and so forth.

The thickness of the organic semiconductor layer is not specifically limited, but properties of the resulting transistor tend to depend largely on the thickness of the organic semiconductor layer. The thickness is ordinarily 1 μm or less, and preferably 10-300 nm, though it depends on the utilized organic semiconductor material.

Each of passivation layer 58 or 59 may consist of an organic layer or of an inorganic layer, but the passivation layer preferably has a layered structure in which an organic layer and an inorganic layer are provided. A material exhibiting no adverse effect on organic semiconductor 7 is preferably used for an organic layer. Preferable examples thereof include polyvinyl alcohol, polyvinyl pyrrolidone, HEMA, an acrylic acid and a homopolymer or a copolymer composed of a component such as acrylamide Employing an aqueous solution containing the above-described materials, the organic layer can be formed by a coating method such as a spray coating method, a spin coating method, a blade coating method or a dip coating method, or a patterning method such as a printing method or an ink-jet method.

The inorganic layer made of inorganic oxide or organic nitride such as silicon dioxide, silicon nitride, aluminum oxide, tantalum oxide, and titanium oxide can be formed by an atmospheric pressure plasma method, a vacuum evaporation method, a molecular beam epitaxial growth method, an ion cluster beam method, a low energy ion beam method, an ion plating method, a CVD method, and a sputtering method; a coating method such as a spray coating method, a spin coating method, a blade coating method or a dip coating method; or a patterning method such as a printing method or an ink-jet method.

### EXAMPLE

Next, the present invention will now be specifically described referring to examples, but the present invention is not limited thereto. Incidentally, “parts” and “%” in the description represent “parts by weight” and “% by weight”, respectively unless otherwise specifically mentioned.

### Example 1

### Preparation of Substrate

### (Preparation of Substrate 1-1)

A PET substrate was subjected to a corona discharge treatment, and immersed in an aqueous 2% by weight ODS (octadecyltriethoxy silane) solution at room temperature for 10 minutes, followed by drying at 120° C. for 30 minutes to obtain substrate 1-1.

(Preparation of Substrate 1-2)

A PET substrate was subjected to a corona discharge treatment, and was subsequently immersed in an aqueous 2% by weight compound A-1 solution at room temperature for 10 minutes, followed by drying at 120° C. for 30 minutes to obtain substrate 1-2.

(Preparation of Substrate 1-3)

A PET substrate was subjected to a corona discharge treatment, and was subsequently immersed in an aqueous 2% by weight compound A-2 solution at room temperature for 10 minutes, followed by drying at 120° C. for 30 minutes to obtain substrate 1-3.

(Preparation of Substrate 1-4)

A PET substrate was subjected to a corona discharge treatment, and was subsequently immersed in an aqueous 2% by weight compound A-3 solution at room temperature for 10 minutes, followed by drying at 120° C. for 30 minutes to obtain substrate 1-4.

[Preparation of Photomask]

(Preparation of Photomask 1-1)

A Cr layer having a thickness of 50 nm was formed on the fused glass by a sputtering method to form a pattern of L/S=10 μm/10 μm by a photolithography method, whereby photomask 1-1 was obtained.

(Preparation of Photomask 1-2)

A Cr layer having a thickness of 50 nm was formed on the fused glass by a sputtering method to form a pattern of L/S=10 μm/10 μm by a photolithography method, and a dispersion formed of titanium dioxide having a primary particle diameter of 10 nm was subsequently coated on the Cr surface by a spin coating method so as to give a dry thickness of 50 nm, followed by calcination at 450° C. to obtain photomask 1-2 having a titanium dioxide layer.

(Preparation of Photomask 1-3)

A Cr layer having a thickness of 50 nm was formed on the fused glass by a sputtering method to form a pattern of L/S=10 μm/10 μm by a photolithography method, and a dispersion formed of titanium dioxide having a primary particle diameter of 10 nm was subsequently coated on the fused quartz surface by a spin coating method so as to give a dry thickness of 50 nm, followed by calcination at 450° C. to obtain photomask 1-3 having a titanium dioxide layer.

(Preparation of Photomask 1-4)

A dispersion formed of titanium dioxide having a primary particle diameter of 10 nm was coated on the fused quartz by a spin coating method so as to give a dry thickness of 50 nm to form a titanium dioxide layer via calcination at 450° C., and a Cr layer having a thickness of 50 nm was subsequently formed on the titanium dioxide layer by a sputtering method to form a pattern of L/S=10 μm/10 μm after etching only the Cr layer by a photography method, whereby photomask 1-4 having a titanium dioxide layer.

<<Preparation of Sample>>

[Preparation of Sample 1-1]

### (Formation of Conductive Pattern)

The Cr layer in photomask 1-1 and the surface having been treated with ODS, of base material 1-1 were closely attached to each other, and were subsequently exposed to light for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-1.

[Preparation of Sample 1-2]

### (Formation of Conductive Pattern)

The Cr layer in photomask 1-1 and the surface having been treated with ODS, of base material 1-1 were closely attached to each other, and were subsequently exposed to light for 10 minutes employing a low-pressure mercury lamp having a main wavelength of 254 nm. The resulting base material was immersed in a Pd catalyst solution, followed by drying, and was further immersed in an electroless copper plating solution, followed by drying to obtain sample 1-2.

[Preparation of Sample 1-3]

### (Formation of Conductive Pattern)

A distance between the surface having been treated with octadecyltriethoxy silane, of base material 1-1, and a titanium dioxide layer in photomask 1-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-3.

[Preparation of Sample 1-4]

### (Formation of Conductive Pattern)

The Cr layer in photomask 1-1 and the surface having been treated with compound A-1, of base material 1-2 were closely attached to each other, and were subsequently exposed to light for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-4.

[Preparation of Sample 1-5]

### (Formation of Conductive Pattern)

A distance between the surface having been treated with compound A-1, of base material 1-3, and a titanium dioxide layer in photomask 1-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-5.

[Preparation of Sample 1-6]

### (Formation of Conductive Pattern)

A distance between the surface having been treated with compound A-2, of base material 1-3, and a titanium dioxide layer in photomask 1-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-6.

[Preparation of Sample 1-7]

### (Formation of Conductive Pattern)

A distance between the surface having been treated with compound A-3, of base material 1-4, and a titanium dioxide layer in photomask 1-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-7.

[Preparation of Sample 1-8]

### (Formation of Conductive Pattern)

A distance between the surface having been treated with compound A-1, of base material 1-2, and a titanium dioxide layer in photomask 1-3 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-8.

[Preparation of Sample 1-9]

### (Formation of Conductive Pattern)

A distance between the surface having been treated with compound A-1, of base material 1-2, and a Cr layer in photomask 1-4 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 1-9.

The configuration of each of the resulting samples as described above is shown in Table 1.

<<Evaluation of Sample>>

### (Evaluation of Adhesiveness)

After a cellophane tape “CT24” produced by Nichiban Co., Ltd. was closely attached onto the sample surface by ball of a finger, the cellophane tape was peeled all at once, and an area ratio of the peeled conductive pattern was determined to evaluate adhesiveness in accordance with the following criteria.

A: No peeled conductive pattern is observed (corresponding to 0 in the classified test result).

B: The conductive pattern has a peeled area of more than 0% and not more than 1.0%.

C: The conductive pattern has a peeled area of more than 1.0% and not more than 5.0%.

D The conductive pattern has a peeled area of more than 5.0%.

### (Evaluation of Fine Line Reproduction)

The sample surface was observed with a microscope VHX-600 manufactured by Keyence Corporation to evaluate fine line reproduction in accordance with the following criteria.

A: A line width as well as a line interval is reproduced in accuracy falling within ±10%.

B: A line width as well as a line interval is reproduced in accuracy falling within ±20%.

C: A line width as well as a line interval is reproduced in accuracy falling within ±50%.

D: A line width as well as a line interval is reproduced in accuracy falling outside the range of ±50%.

Evaluation results are shown in Table 1.

TABLE 1

| | Base material | | Method of forming conductive pattern | | | | | | | |
|---|---|---|---|---|---|---|---|---|---|---|
| | | Silane | Photomask | | Light exposure | | | Evaluation results | | |
| Sample | | coupling | | Photocatalyst | | Main | Plating | Fine line | | |
| No. | No. | agent | No. | Presence/Absence | Light source | wavelength | treatment | reproduction | Adhesiveness | Remarks |
| 1-1 | 1-1 | ODS | 1-1 | Absence | High-pressure | 365 nm | Electroless | D | C | Comparative |
| | | | | | mercury lamp | | copper plating | | | example |
| 1-2 | 1-1 | ODS | 1-1 | Absence | Low-pressure | 254 nm | Electroless | B | D | Comparative |
| | | | | | mercury lamp | | copper plating | | | example |
| 1-3 | 1-1 | ODS | 1-2 | Presence | High-pressure | 365 nm | Electroless | C | C | Comparative |
| | | | | | mercury lamp | | copper plating | | | example |
| 1-4 | 1-2 | A-1 | 1-1 | Absence | High-pressure | 365 nm | Electroless | D | B | Comparative |
| | | | | | mercury lamp | | copper plating | | | example |
| 1-5 | 1-2 | A-1 | 1-2 | Presence | High-pressure | 365 nm | Electroless | A | A | Present |
| | | | | | mercury lamp | | copper plating | | | invention |
| 1-6 | 1-3 | A-2 | 1-2 | Presence | High-pressure | 365 nm | Electroless | B | A | Present |
| | | | | | mercury lamp | | copper plating | | | invention |
| 1-7 | 1-4 | A-3 | 1-2 | Presence | High-pressure | 365 nm | Electroless | B | A | Present |
| | | | | | mercury lamp | | copper plating | | | invention |
| 1-8 | 1-2 | A-1 | 1-3 | Presence | High-pressure | 365 nm | Electroless | A | A | Present |
| | | | | | mercury lamp | | copper plating | | | invention |
| 1-9 | 1-2 | A-1 | 1-4 | Presence | High-pressure | 365 nm | Electroless | A | A | Present |
| | | | | | mercury lamp | | copper plating | | | invention |

ODS: octadecyltriethoxy silane,
A-1: triethoxysilyl-propylamino-triazine-dithiol
A-2: γ-mercaptopropyl-trimethoxy silane,
A-3: 3-mercaptopropylmethyldimethoxy silane

As is clear from Table 1, it is to be understood that each of samples of the present invention prepared by conducting a plating treatment after the base material having been treated with a compound represented by Formula (1) in the present invention with a photomask possessing a titanium dioxide layer exhibiting photocatalytic action is exposed to light has superior adhesiveness between a substrate and a conductive pattern and higher fine line reproduction to those of comparative samples

### Example 2

### Preparation of Photomask

(Preparation of Photomask 1-1)

(Preparation of Photomask 2-1)

Photomask 2-1 was obtained similarly to preparation of photomask 1-1 in Example 1, except that pattern shapes are shapes for a source electrode and a drain electrode.

(Preparation of Photomask 2-2)

Photomask 2-2 was obtained similarly to preparation of photomask 1-2 in Example 1, except that pattern shapes are shapes for a source electrode and a drain electrode.

(Preparation of Photomask 2-3)

Photomask 2-3 was obtained similarly to preparation of photomask 1-3 in Example 1, except that pattern shapes are shapes for a source electrode and a drain electrode.

(Preparation of Photomask 2-)

Photomask 2-4 was obtained similarly to preparation of photomask 1-4 in Example 1, except that pattern shapes are shapes for a source electrode and a drain electrode.

<<Preparation of Sample>>

[Preparation of Sample 2-1]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight ODS solution at room temperature for 10 minutes, followed by drying at 120° C. for 30 minutes.

Next, the Cr layer in photomask 2-1 and the surface having been treated with ODS were closely attached to each other, and were subsequently exposed to light for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-1 in which a source electrode and a drain electrode were formed.

[Preparation of Sample 2-2]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight ODS solution at room temperature for 10 minutes, followed by drying at 120° C. for 30 minutes.

Next, the Cr layer in photomask 2-1 and the surface having been treated with ODS were closely attached to each other, and were subsequently exposed to light for 10 minutes employing a low-pressure mercury lamp having a main wavelength of 254 nm. The resulting base material was immersed in a Pd catalyst solution, followed by drying, and was further immersed in an electroless copper plating solution, followed by drying to obtain sample 2-2 in which a source electrode and a drain electrode were formed.

[Preparation of Sample 2-3]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of gate insulating film 4 was subjected to a UV ozone treatment, and the entire substrate was subsequently immersed in an aqueous 2% by weight ODS solution at room temperature for 10 minutes, followed by drying at 120° C. for 30 minutes.

Next, a distance between the surface having been treated with ODS and a titanium dioxide layer in photomask 2-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-3 in which a source electrode and a drain electrode were formed.

[Preparation of Sample 2-4]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight compound A-1 solution at room temperature for 10 minutes, followed by drying at 120° C. for 30 minutes.

Next, the Cr layer in photomask 2-1 and the surface having been treated with compound A-1 were closely attached to each other, and were subsequently exposed to light for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-4 in which a source electrode and a drain electrode were formed.

[Preparation of Sample 2-5]

An aluminum-neodymium (AlNd) film having a thickness of 150 nm as an aluminum system alloy was formed on glass substrate 1 by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain gate insulating film 4

Next, the surface of the gate insulating film was subjected to a UV ozone treatment, and the entire substrate was subsequently immersed in an aqueous 2% by weight compound A-1 solution at room temperature for 10 minutes, followed by drying at 120° C. for 30 minutes.

Next, a distance between the surface having been treated with compound A-1 and a titanium dioxide layer in photomask 2-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-5 in which a source electrode and a drain electrode were formed.

[Preparation of Sample 2-6]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of gate insulating film 4 was subjected to a UV ozone treatment, and the entire substrate was subsequently immersed in an aqueous 2% by weight compound A-2 solution at room temperature for 10 minutes, followed by drying at 120° C. for 30 minutes.

Next, a distance between the surface having been treated with compound A-2 and a titanium dioxide layer in photomask 2-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-6 in which a source electrode and a drain electrode were formed.

[Preparation of Sample 2-7]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight compound A-3 solution at room temperature for 10 minutes, followed by drying at 120° C. for 30 minutes.

Next, a distance between the surface having been treated with compound A-3 and a titanium dioxide layer in photomask 2-2 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-7 in which a source electrode and a drain electrode were formed.

[Preparation of Sample 2-8]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight compound A-1 solution at room temperature for 10 minutes, followed by drying at 120° C. for 30 minutes.

Next, a distance between the surface having been treated with compound A-1 and a titanium dioxide layer in photomask 2-3 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-7 in which a source electrode and a drain electrode were formed.

[Preparation of Sample 2-9]

An aluminum-neodymium (AlNd) film having a thickness of 150 nm as an aluminum system alloy was formed on a glass substrate by a sputtering method. The AlNd film was subjected to a photolithography treatment and an etching treatment to form a gate electrode and a contact electrode. Thereafter, a SiO₂ film having a thickness of 300 nm was formed by a plasma CVD method to obtain a gate insulating film.

Next, the surface of the gate insulating film was subjected to a UV ozone treatment, and the entire substrate was subsequently immersed in an aqueous 2% by weight compound A-1 solution at room temperature for 10 minutes, followed by drying at 120° C. for 30 minutes.

Next, a distance between the surface having been treated with compound A-1 and a Cr layer in photomask 2-4 was set to 50 nm, and exposure to light was conducted for 10 minutes employing a high-pressure mercury lamp having a main wavelength of 365 nm. The resulting base material was immersed in a Pd catalyst solution, followed by drying, and was further immersed in an electroless copper plating solution, followed by drying to obtain sample 2-9 in which a source electrode and a drain electrode were formed.

The configuration of each sample obtained as described above is shown in Table 2.

<<Evaluation of Sample>>

(Evaluation of Adhesiveness and Fine Line Reproduction)

Adhesiveness and fine line reproduction were evaluated similarly to Example 1.

(Evaluation of Element Characteristic)

Organic thin film transistors were prepared by a method described below employing samples prepared as described above.

A 6,13-bistriisopropylsilylethinyl pentacene (hereinafter, referred to as pentacene) solution was dropped as an organic semiconductor material solution roughly in the center of a source electrode and a drain electrode in each sample to form an organic semiconductor layer so as to cover the drain electrode and the source electrode. In this case, the dropped pentacene solution amount was designed to be set to a dropping amount which was previously determined by the experiments in such a way that when forming the organic semiconductor layer via volatilization of a solvent, a thickness of 50 nm was obtained.

Next, PVA124C (product name; nonphotosensitive polyvinyl alcohol resin produced by KURARAY Co., Ltd.) was formed as a passivation layer having a thickness of 2 μm by a spin coating method, and was subjected to a photolithography treatment and an etching treatment for removal of undesired portions to obtain a passivation layer.

Next, a passivation layer having a thickness of 50 nm, which is formed of SiO₂, was formed by an atmospheric plasma method.

Next, PC403 (product name; produced by JSR CORP.) was coated on the passivation layer as a photosensitive insulating film having a thickness of 1 μm. Thereafter, PC403 was used as a resist, and a photolithography treatment (light exposure and development) was conducted to form contact holes to connect a drain electrode to the after-mentioned pixel electrode. Specifically, PC403 as a photosensitive insulating film was removed from contact hole portions via the mask light exposure and a developing treatment, followed by washing with water, whereby a part of the drain electrode was exposed via removal of PVA124C as a passivation layer at exposed portions.

Next, an ITO (Indium Tin Oxide) film having a thickness of 150 nm was formed by a sputtering method to form a pixel electrode, and subsequently, a photolithography treatment and an etching treatment were conducted to form a contact electrode and a pixel electrode. Thus, an organic thin film transistor was prepared.

The switching characteristic as an indicator of an element property of the resulting organic thin film transistor was evaluated in accordance with the following criteria.

A: An ON/OFF ratio of at least 10⁵

B: An ON/OFF ratio of at least 10³ and less than 10⁵

C: An ON/OFF ratio of less than 10³

D: Inoperative

Evaluation results concerning “adhesiveness”, “fine line reproduction” and “element property” are shown in Table 2.

TABLE 2

| | | | Method of forming conductive pattern | | | | | | | | |
|---|---|---|---|---|---|---|---|---|---|---|---|
| | Base material | | Photomask | | | | | | | | |
| | | Silane | | Photocatalyst | Light exposure | | | Evaluation results | | | |
| Sample | | coupling | | Presence/ | | Main | | Fine line | Adhesive- | Element | |
| No. | No. | agent | No. | Absence | Light source | wavelength | Plating treatment | reproduction | ness | property | Remarks |
| 2-1 | 2-1 | ODS | 2-1 | Absence | High-pressure | 365 nm | Electroless | D | C | D | Comp. |
| | | | | | mercury lamp | | copper plating | | | | |
| | | | | | | | and gold plating | | | | |
| 2-2 | 2-1 | ODS | 2-1 | Absence | Low-pressure | 254 nm | Electroless | B | D | D | Comp. |
| | | | | | mercury lamp | | copper plating | | | | |
| | | | | | | | and gold plating | | | | |
| 2-3 | 2-1 | ODS | 2-2 | Presence | High-pressure | 365 nm | Electroless | C | C | D | Comp. |
| | | | | | mercury lamp | | copper plating | | | | |
| | | | | | | | and gold plating | | | | |
| 2-4 | 2-2 | A-1 | 2-1 | Absence | High-pressure | 365 nm | Electroless | D | B | D | Comp. |
| | | | | | mercury lamp | | copper plating | | | | |
| | | | | | | | and gold plating | | | | |
| 2-5 | 2-2 | A-1 | 2-2 | Presence | High-pressure | 365 nm | Electroless | A | A | A | Inv. |
| | | | | | mercury lamp | | copper plating | | | | |
| | | | | | | | and gold plating | | | | |
| 2-6 | 2-3 | A-2 | 2-2 | Presence | High-pressure | 365 nm | Electroless | B | A | B | Inv. |
| | | | | | mercury lamp | | copper plating | | | | |
| | | | | | | | and gold plating | | | | |
| 2-7 | 2-4 | A-3 | 2-2 | Presence | High-pressure | 365 nm | Electroless | B | A | B | Inv. |
| | | | | | mercury lamp | | copper plating | | | | |
| | | | | | | | and gold plating | | | | |
| 2-8 | 2-2 | A-1 | 2-3 | Presence | High-pressure | 365 nm | Electroless | A | A | A | Inv. |
| | | | | | mercury lamp | | copper plating | | | | |
| 2-9 | 2-2 | A-1 | 2-4 | Presence | High-pressure | 365 nm | Electroless | A | A | A | Inv. |
| | | | | | mercury lamp | | copper plating | | | | |

ODS: octadecyltriethoxy silane,
A-1: triethoxysilyl-propylamino-triazine-dithiol
A-2: γ-mercaptopropyl-trimethoxy silane,
A-3: 3-mercaptopropylmethyldimethoxy silane
Comp.: Comparative example,
Inv.: Present invention

As is clear from Table 2, it was to be understood that samples of the present invention exhibited excellent adhesion of a conductive pattern to a substrate, and high fine line reproduction in comparison to those of comparative examples. It was also to be understood that samples of the present invention exhibited superior switching properties to those of comparative examples, when operating each of organic thin film transistors.

### EXPLANATION OF NUMERALS

TFT Organic Thin Film Transistor
11, 51 Substrate
12 Base material
21 Layer containing a compound represented by Formula (1)
22 Region where a compound represented by Formula (1) is decomposed
31 Copper
40 Photomask
41 Fused quartz
42 Titanium dioxide layer
43 Cr layer
52 Gate electrode
53 Contact electrode
54 Insulating film
55 Source electrode
56 Drain electrode
57 Organic semiconductor layer
58, 59 Passivation layer
60 Photosensitive insulating layer
61 Pixel electrode

1. A method of forming a conductive pattern on a substrate surface, comprising the steps of:
treating the substrate surface employing a compound represented by the following Formula (1);
decomposing the compound represented by Formula (1) via a photocatalytic action; and
conducting a plating treatment after decomposing the compound represented by Formula (1),
(R)ₙ—Si(A)₃₋ₙ-(B) Formula (1)
wherein R represents an alkyl group having 8 carbon atoms or less, A represents an alkoxy group or a halogen atom, B represents a substituent comprising a SH group, and n represents an integer of 0-2.

2. The method of claim 1,
wherein the compound represented by Formula (1) comprises a triazine ring.

3. The method of claim 1,
wherein the photocatalytic action comprises a titanium dioxide photocatalytic action.

4. The method of claim 3,
wherein the step of decomposing the compound represented by Formula (1) comprises a light exposure step employing a photomask in which a titanium dioxide film is comprised.

5. The method of claim 4,
wherein a light source used in the light exposure step has a main wavelength of 300-400 nm.

6. The method of claim 5,
wherein the light source comprises a high-pressure mercury lamp.

7. The method of claim 1,
wherein the plating step comprises a catalyst-carrying process and an electroless plating treatment process.

8. An organic thin film transistor comprising a conductive pattern formed by the method of claim 1.

9. The organic thin film transistor of claim 8,
wherein the conductive pattern comprises a source electrode or a drain electrode.

10. A method of forming a conductive pattern on a substrate surface, comprising the steps of:
treating the substrate surface employing a compound represented by the following Formula (1);
decomposing the compound represented by Formula (1) via a photocatalytic action; and
conducting a plating treatment after decomposing the compound represented by Formula (1),
(R)ₙ—Si(A)₃₋ₙ-(B) Formula (1)
wherein R represents an alkyl group having 8 carbon atoms or less, A represents an alkoxy group or a halogen atom, B represents a substituent comprising a SH group, and n represents an integer of 0-2,
wherein the compound represented by Formula (1) comprises a triazine ring, and
wherein the photocatalytic action comprises a titanium dioxide photocatalytic action.

11. The method of claim 10,
wherein the step of decomposing the compound represented by Formula (1) comprises a light exposure step employing a photomask in which a titanium dioxide film is comprised.

12. The method of claim 11,
wherein a light source used in the light exposure step has a main wavelength of 300-400 nm.

13. The method of claim 12,
wherein the light source comprises a high-pressure mercury lamp.

14. The method of claim 10,
wherein the plating step comprises a catalyst-carrying process and an electroless plating treatment process.

15. An organic thin film transistor comprising a conductive pattern formed by the method of claim 10.

16. The organic thin film transistor of claim 15,
wherein the conductive pattern comprises a source electrode or a drain electrode.
